(19) United States
(12) Patent Application Publication
(10) Pub. No.: US 2025/0372434 A1
(43) Pub. Date: Dec. 4, 2025

(54) Methods And Systems For Chucking Highly Bowed Semiconductor Wafers

(71) Applicant: KLA Corporation, Milpitas, CA (US)

(72) Inventor: Michel Pharand, Los Gatos, CA (US)

(21) Appl. No.: 19/052,832

(22) Filed: Feb. 13, 2025

Related U.S. Application Data
(60) Provisional application No. 63/652,669, filed on May 28, 2024.

(51) Int. Cl. H01L 21/683; H01L 21/68

(52) U.S. Cl. CPC H01L 21/6838; H01L 21/681

(57) ABSTRACT

Methods and systems for vacuum mounting a highly

bowed, thin substrate, such as a semiconductor wafer, onto a flat chuck are presented herein. A vacuum reservoir assembly including a high flow vacuum port connector is located in close proximity to a wafer positioning system. A wafer positioning system includes a wafer chuck assembly having a complementary high flow vacuum port connector. In a docked position, the high flow vacuum port connector and the complementary high flow vacuum port connector are fluidically coupled, and a flow control valve is opened to clamp a highly bowed wafer. Any vacuum conduit between the vacuum reservoir and the vacuum port connector is short in length and large in diameter to minimize frictional losses. In this manner, increased vacuum flow is able to compensate for large leaks and generate enough negative pressure to successfully clamp a highly bowed wafer.

### CROSS REFERENCE TO RELATED APPLICATION

The present application for patent claims priority under 35 U.S.C. §119 from U.S. provisional patent application serial number 63/652,669, filed May 28, 2024, the subject matter of which is incorporated herein by reference in its entirety.

### TECHNICAL FIELD

The described embodiments relate to systems for specimen handling, and more particularly to clamping a highly bowed wafer to a flat wafer chuck.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography, among others, is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

A lithographic process, as described above, is performed to selectively remove portions of a resist material overlaying the surface of a wafer, thereby exposing underlying areas of the specimen on which the resist is formed for selective processing such as etching, material deposition, implantation, and the like. Therefore, in many instances, the performance of the lithography process largely determines the characteristics (e.g., dimensions) of the structures formed on the specimen. Consequently, the trend in lithography is to design systems and components (e.g., resist materials) that are capable of forming patterns having ever smaller dimensions. In particular, the resolution capability of the lithography tools is one primary driver of lithography research and development.

Inspection processes based on optical metrology are used at various steps during a semiconductor manufacturing process to detect defects on wafers to promote higher yield. Optical metrology techniques offer the potential for high throughput without the risk of sample destruction. A number of optical metrology based techniques including scatterometry implementations and associated analysis algorithms to characterize device geometry have been described.

A wafer is positioned within a wafer processing tool (e.g., lithography tool, etch tool, inspection tool, metrology tool, etc.) by clamping the thin wafer to a flat wafer chuck. The wafer chuck is a machine part that provides the interface between the wafer and the rest of the machine. The wafer is positioned within the tool by precisely controlling the movements of the wafer chuck to which the wafer is attached.

The dimensions of the surface of the wafer chuck that interface with the wafer are precisely manufactured and maintained during the operation of the tool.

Wafers themselves are very thin (e.g., 200 micrometers to 1.5 millimeters thick) and have relatively large diameters (e.g., 200 millimeter, 300 millimeters, or more). For this reason, the shape of a wafer is not particularly stable in its unconstrained (i.e., unsupported) state. This is particularly true for wafer flatness. During processing, the wafer is clamped to the wafer chuck over a large portion of its backside surface area. By forcing the wafer to conform to the shape of the wafer chuck, the wafer chuck flattens the wafer, so that wafer processing and inspection tasks can be completed successfully.

Recent advances in semiconductor manufacturing technology require the deposition of many film layers with different electrical and mechanical properties. Film deposition is performed at elevated temperatures. As a processed wafer cools, residual stress exists between the film layer and the underlying substrate. Because the film is deposited above the neutral axis of the wafer, the wafer is subject to a bending moment induced by the residual stress between the cooled film and the underlying substrate that causes the wafer to bow. Depending on the characteristics of the film layer, the wafer bow may be convex or concave.

Furthermore, the crystalline nature of a silicon wafer exhibits a different modulus of elasticity along different axes of the crystal structure. As a result, the induced bending moment is not symmetrical. In general, the displacement of the wafer in a direction normal to the wafer surface due to wafer bow may be several millimeters for a 300 millimeter wafer.

In many examples, wafers are clamped to the wafer chuck by vacuum. As the wafer is lowered onto the wafer, the backside wafer surface comes into contact with the chuck and covers vacuum channels machined into the surface of the wafer chuck. As the wafer covers the vacuum channels, the vacuum supplied at the channels effectively pulls the wafer down onto the surface of wafer chuck and maintains the wafer in the clamped position as long as vacuum is maintained at the channels. Typically, wafer metrology employed to measure wafer films and critical dimensions requires wafer flatness of less than 60 arc- seconds of local wafer tilt. As such, a wafer is clamped down to a wafer chuck surface that exceeds these flatness requirements.

Unfortunately, this approach to clamping the wafer to the surface of the wafer chuck is problematic when the wafer is highly bowed (e.g., backside wafer surface facing surface of wafer chuck is concave or convex). In some examples, 300 millimeter diameter wafers exhibit variation in flatness from hundreds of micrometers (e.g., 500 micrometers) to several millimeters (e.g., 8-10 millimeters). When a wafer is extremely bowed (e.g., flatness variation exceeding one millimeter), the wafer does not uniformly cover the vacuum channels of the wafer chuck. This results in large vacuum leaks that reduce the clamping force exerted by each vacuum channel. In many scenarios, the reduced clamping force is unable to achieve adequate force levels required to pull the wafer from its deformed state down onto the wafer chuck. As a result, the wafer chuck is unable to adequately constrain the wafer and further processing of the wafer is not possible without additional intervention. In these scenarios, the wafer may have to be discarded or specially processed to reduce wafer bow.

Current high precision wafer positioning systems employ a dynamic cable routed from the machine frame to the wafer chuck via the long stroke stage axes, e.g., the X and Y axes. The dynamic cable includes a dedicated vacuum line, a dedicated pressurized pneumatic line, or both. If a pressurized line is employed, a venturi is located in close proximity to the wafer chuck to generate vacuum from the flow of positively pressurized air.

Unfortunately, a dynamic cable routed from the machine frame to the wafer chuck is lengthy and any dedicated vacuum or pressurized pneumatic line routed through the long stroke stage axes has a small diameter. Consequently, air flow through pressurized air or vacuum lines is subject to significant pressure loss due to friction effects. The number of vacuum or pressurized air supply lines routed through the dynamic cable, the diameter of vacuum or pressurized air supply lines routed through the dynamic cable, or both, may be increased to reduce pressure losses. However, this also increases the mass and stiffness of the dynamic cable, which, in turn, increases the magnitude of undesirable force disturbances to the wafer positioning system. These force disturbances undermine wafer positioning performance during wafer processing operations. For these reasons, simply upsizing vacuum or air pressure supply infrastructure to realize high vacuum flows is undesirable from both design and operational perspectives (e.g., increased design complexity, increased cost, and loss of wafer positioning performance).

Improved methods and systems for chucking highly bowed wafers in semiconductor processing equipment are desired.

### SUMMARY

Methods and systems for vacuum mounting a highly bowed, thin substrate, such as a semiconductor wafer, onto a flat chuck are presented herein. A vacuum reservoir assembly including a high flow vacuum port connector is located in close proximity to a wafer positioning system. A wafer positioning system includes a wafer chuck assembly having a complementary high flow vacuum port connector. In a docked position, the high flow vacuum port connector and the complementary high flow vacuum port connector are fluidically coupled, and a flow control valve is opened to clamp a highly bowed wafer. Any vacuum conduit between the vacuum reservoir and the vacuum port connector is short in length and large in diameter to minimize frictional losses. In this manner, increased vacuum flow is able to compensate for large leaks and generate enough negative pressure to successfully clamp a highly bowed wafer.

When a wafer is flattened against the top surface of a wafer chuck, the bottom surface of the wafer is sealed against the top surface of wafer chuck. In this state, very little vacuum flow is required to maintain the wafer in a chucked state. In this state, very low flow rate through a dynamic cable is sufficient to maintain the wafer in the chucked state.

In a further aspect, the vacuum reservoir is fluidically coupled to a vacuum source configured to

maintain the pressure of the vacuum reservoir. The vacuum reservoir is fluidically coupled to the wafer chuck only when the wafer chuck is positioned in the docked position. Otherwise, the wafer chuck is decoupled from the vacuum reservoir and the flow control valve is closed. During this time, the vacuum source evacuates the vacuum reservoir to achieve a desired negative pressure within the vacuum reservoir. In this manner, the vacuum reservoir is prepared to induce high flow from the wafer chuck to the vacuum reservoir when the next highly bowed wafer must be clamped onto the top surface of the wafer chuck.

In some embodiments, the wafer positioning system moves the wafer chuck horizontally to the docked position. In these embodiments the direction of engagement of the high flow vacuum port connector and the complementary high flow vacuum port connector is in the horizontal plane. In some other embodiments, the wafer positioning system moves the wafer chuck vertically to the docked position. In these embodiments the direction of engagement of the high flow vacuum port connector and the complementary high flow vacuum port connector is perpendicular to the horizontal plane. In general, the direction of engagement may be oriented in any suitable direction.

In some embodiments, a high flow vacuum port connector and a complementary high flow vacuum port connector are not in physical contact when fluidically coupled, e.g., during a high flow. A non-contact fluidic coupling may be advantageous for a number of reasons. First, the non-contact fluidic coupling eliminates disturbance forces from being transmitted from the vacuum reservoir assembly to the wafer positioning system via the fluidic coupling. Second, the non-contact fluidic coupling eliminates any mechanical coupling of mass, mechanical stiffness, or both, from the vacuum reservoir assembly to the wafer positioning system. This prevents potential degradation or destabilization of positioning performance on the part of the wafer positioning system.

In some embodiments, a high flow vacuum port connector and a complementary high flow vacuum port connector are in physical contact when fluidically coupled, e.g., during a high flow. In some of these embodiments, the high flow vacuum port connector, the complementary high flow vacuum port connector, or both, include a bellows structure.

In a further aspect, a measurement system includes an actuator subsystem configured to move the high flow vacuum port connector with respect to the machine frame in a direction aligned with a direction of engagement of the high flow vacuum port connector and the complementary high flow vacuum port connector to realize the fluidic coupling between the two.

The foregoing is a summary and thus contains, by necessity, simplifications, generalizations and omissions of detail. Consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a simplified schematic view of one embodiment of measurement system capable of vacuum mounting a highly bowed, thin substrate, such as a semiconductor wafer, onto a flat chuck as described herein.

FIGS. 2A-C illustrate a high flow vacuum port connector and a complementary high flow vacuum port connector moving with respect to one another along a direction of engagement from an undocked state to a docked state in one embodiment.

FIGS. 3A-C illustrate a high flow vacuum port connector and a complementary high flow vacuum port connector moving with respect to one another along a direction of engagement from an undocked state to a docked state in another embodiment.

FIG 4 is a diagram illustrative of an actuator subsystem configured to move a high flow vacuum port connector of a vacuum reservoir assembly toward a complementary high flow vacuum port connector along a direction of engagement in one embodiment.

FIG 5 is plot illustrative of a reservoir pressure and induced volumetric flow rate from a wafer chuck to a volumetric reservoir over a period of time before and after a flow control valve is opened in one example.

FIG 6 is a flowchart illustrative of an exemplary method 200 useful for vacuum clamping and unclamping warped substrates onto a vacuum chuck in several novel aspects.

### DETAILED DESCRIPTION

Reference will now be made in detail to background examples and some embodiments of the invention, examples of which are illustrated in the accompanying drawings.

Methods and systems for vacuum mounting a highly bowed, thin substrate, such as a semiconductor wafer, onto a flat chuck are presented herein. A vacuum reservoirassembly including a high flow vacuum port connector is located in close proximity to a wafer positioning system. The vacuum reservoir is attached, directly or indirectly, to the machine frame, rather than the being routed through a dynamic cable of the wafer positioning system. Thus, any vacuum conduit between the vacuum reservoir and the vacuum port connector is short in length and large in diameter to minimize frictional losses.

In some embodiments, a vacuum reservoir mounted to a machine frame of a wafer processing system in close proximity to a wafer chuck provides significantly higher vacuum flow rate than systems employing vacuum supplied via a dynamic cable, e.g., 2-10 times greater vacuum flow rate.

In one aspect, a vacuum reservoir assembly including a high flow vacuum port connector is located in close proximity to a wafer positioning system. The wafer positioning system includes a wafer chuck assembly having a complementary high flow vacuum port connector. In a docked position, the high flow vacuum port connector and the complementary high flow vacuum port connector are fluidically coupled, enabling high flow from the wafer chuck to the vacuum reservoir with relatively small frictional losses. In this manner, increased vacuum flow is able to compensate for large leaks and generate enough negative pressure, i.e., pressure below atmospheric pressure, to successfully clamp a highly bowed wafer.

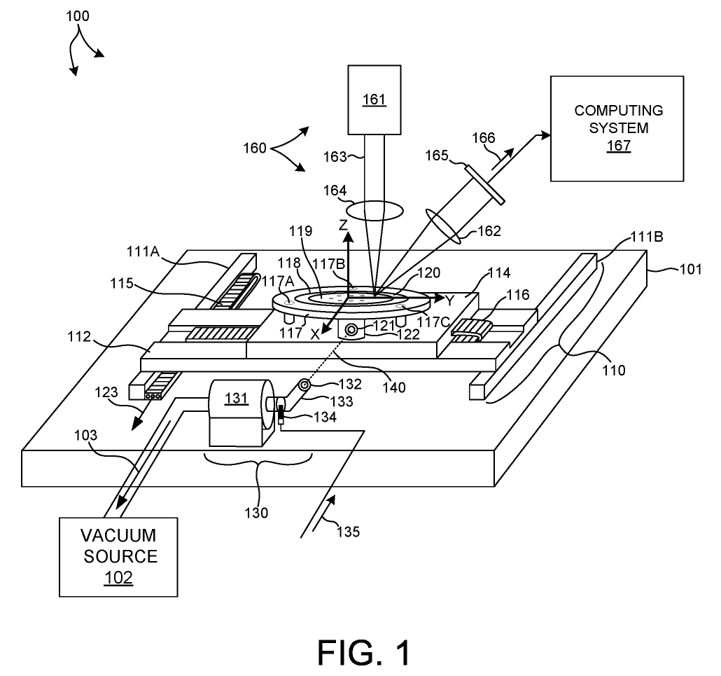

FIG. 1 is a diagram illustrative of a measurement system 100 including a machine frame 101, a wafer positioning system 110, a vacuum reservoir assembly 130, and a semiconductor measurement system 160. As depicted in FIG. 1, wafer positioning system 110 is mechanically coupled to machine frame 101. Wafer positioning system 110 includes multiple motion stages that operate in coordination to move wafer 119 with respect to machine frame 101 in six degrees of freedom. Although wafer positioning system 110 is described herein as a six degree of freedom positioning system, in general, any wafer positioning system employed to locate a wafer in at least one degree of freedom is contemplated within the scope of this patent document.

As depicted in FIG. 1, wafer positioning system 110 includes a long stroke base stage including base reference structures 111A and 111B and X-frame 112. Base reference structures 111A and 111B are mechanically coupled to machine frame 110. X-frame 112 is mechanically constrained by bearing elements (not shown) to move with respect to base reference structures 111A and 111B in one degree of freedom that is approximately aligned with the X-direction depicted in FIG. 1. A base stage drive mechanism (not shown) generates drive forces to move X-frame 112 with respect to base reference structures 111A and 111B.

Wafer positioning system 110 also includes a long stroke intermediate stage including Y-frame 114 moveable with respect to X-frame 112. Y-frame 114 is mechanically constrained by bearing elements (not shown) to move with respect to X-frame 112 in one degree of freedom that is approximately aligned with the Y-direction depicted in FIG.1. An intermediate stage drive mechanism (not shown) generates drive forces to move Y-frame 114 with respect to X-frame 112.

By way of non-limiting example, bearing elements of the base and intermediate stages may include mechanical linear bearings, linear air bearings, linear magnetic bearings, etc. In general, any suitable linear bearing arrangement may be contemplated within the scope of this patent document.

By way of non-limiting example, a base stage and intermediate stage drive mechanisms may include a linear motor, a rotary motor and ball spindle, a rotary motor and belt drive, etc. In general, any suitable stage drive mechanism may be contemplated within the scope of this patent document. The base stage and intermediate stage are long stroke motion stages, e.g., total stroke of more than 100 millimeters.

Wafer positioning system 110 also includes a tip/tilt/Z stage 117 moveable with respect to Y-frame 114. Tip/tilt/Z stage 117 includes three linear actuators 117A-C configured to independently move tip/tilt/Z stage 117 linearly with respect to intermediate stage 114 in the Z- direction and rotate tip/tilt/stage 117 about the X and Y axes, in any combination of rotational and linear motions. Tip/tilt/Z stage 117 is a short stroke motion stage, e.g., total stroke of actuators 117A-C is less than 10 millimeters. By way of non-limiting example, linear actuators 117A-C may include a piezoelectric linear motor, a Lorentz coil motor, etc. In general, any suitable stage drive mechanism may be contemplated within the scope of this patent document.

Wafer positioning system 110 also includes a rotary stage including wafer chuck 120 constrained to rotate with respect to tip/tilt/Z stage 117. A rotary bearing is configured to constrain the movement of wafer chuck 120 with respect to tip/tilt/Z stage 117 to rotation about the Z-axis. By way of non-limiting example, bearing elements of the rotary stage may include mechanical bearings, air bearings, magnetic bearings, etc. In general, any suitable rotary bearing arrangement may be contemplated within the scope of this patent document.

A rotary bearing motor assembly 118 is configured to provide rotational torque to rotate wafer chuck 120 with respect to tip/tilt/Z stage 117 about the Z-axis. By way of non-limiting example, rotary motor assembly 118 may include a rotary motor and belt drive arrangement, a direct drive electric motor having rotor and stator elements mounted to the wafer chuck 120 and tip/tilt/Z stage 117, respectively, or vice-versa, etc. In general, any suitable rotary drive arrangement may be contemplated within the scope of this patent document.

Wafer 119 is clamped on the top surface of wafer chuck 120. In this manner, wafer positioning system 110 is configured to move wafer 119 is six degrees of freedom: linear motion in aligned with the X, Y, and Z axes, and rotational motion about the X, Y, and Z axes.

As depicted in FIG 1 , wafer positioning system 110 includes a dynamic cable system including dynamic cable 115 coupled to machine frame 101 and X-frame 112 and dynamic cable 116 coupled to X-frame 112 and Y-frame 114. Dynamic cable 115 provides routing for electrical wiring, positively pressurized air conduits, negatively pressurized air conduits, etc., between machine frame 101 and X-frame 112. Dynamic cable 116 provides routing for electrical wiring, positively pressurized air conduits, negatively pressurized air conduits, etc., between X-frame 112 and Y- frame 114. In the embodiment depicted in FIG 1 , negatively pressurized air 123 is routed from machine frame 101 through dynamic cable 115, through X-frame 112, through dynamic cable 116, through Y-frame 114, through vacuum feedthrough 122 to wafer chuck 120. In this manner, vacuum is provided from machine frame 101 to wafer chuck 120 to maintain wafer 119 clamped onto the top surface of wafer chuck 120.

As depicted in FIG. 1, vacuum feedthrough 122 is mechanically coupled to Y-frame 114. Vacuum feedthrough 122 provides a vacuum conduit between Y-frame 114 and wafer chuck 120 that allows for a limited amount of relative motion between wafer chuck 120 and Y-frame 114. In some embodiments, vacuum feedthrough 122 also includes a complementary high flow vacuum port connector 121 and provides a vacuum conduit between the complementary high flow vacuum port connector 121 and wafer chuck 120.

In some other embodiments, complementary high flow vacuum port connector 121 is coupled to wafer chuck 120 directly. In these embodiments, wafer chuck 120 includes a vacuum conduit from complementary high flow vacuum port connector 121 to wafer chuck 120.

As depicted in FIG 1 , vacuum reservoir assembly 130 includes a vacuum reservoir 131 mechanically coupled to machine frame 101. High flow vacuum port connector 132 is fluidically coupled to vacuum reservoir 131 via vacuum conduit 133. Flow control valve 134 is disposed in the fluidic path between the vacuum reservoir 131 and the high flow vacuum port connector 132.

In one aspect, a wafer positioning system is configured to move the wafer chuck assembly to a docked position. In the docked position, a complementary high flow vacuum port connector of the wafer chuck assembly is fluidically coupled with a high flow vacuum port connector of a vacuum reservoir assembly. In an undocked position, the complementary high flow vacuum port connector is fluidically decoupled from the high flow vacuum port connector.

As depicted in FIG. 1, wafer positioning system 110 is configured to move complementary high flow vacuum port connector 121 along a direction of engagement 140 to a docked position. In the docked position a fluidic coupling between complementary high flow vacuum port connector 121 and high flow vacuum port connector 132 is achieved. Once the fluidic coupling is achieved, a control signal 135 is communicated to flow control valve 134 causing flow control valve 134 to open causing a high flow from wafer chuck 120 to vacuum reservoir 131.

As depicted in FIG. 1, vacuum reservoir 131 is in close proximity to wafer chuck 120 when wafer chuck 120 is located in the docked position. The volume of the vacuum reservoir 131 is large in comparison to the internal volume of the vacuum channels of the wafer chuck 120. In some embodiments, the internal volume of vacuum reservoir 131 is at least five times the internal volume of the vacuum channels of wafer chuck 120. Furthermore, vacuum conduit 133 is both relatively short in length and relatively large in diameter compared to any vacuum conduit routed through dynamic cables 115 and 116. As a result, vacuum conduit 133 offers very low resistance to flow compared to any vacuum conduit routed through dynamic cables 115 and 116. In some embodiments, the fluidic path from vacuum reservoir 131 to wafer chuck 120 in the docked position is less than one meter.

When flow control valve 134 is opened, high flow is induced over a short duration. In some examples, the volumetric flow rate through vacuum conduit 133 is at least ten times higher than the volumetric flow rate through any vacuum conduit routed through dynamic cables 115 and 116. This generates a large pressure differential between the top surface of wafer 119 (atmospheric pressure) and the bottom surface of wafer 119 (the negative pressure induced by the high flow of air from wafer chuck 120 to vacuum reservoir 131. The large pressure differential generates force over area that flattens wafer 119 onto the surface of wafer chuck 120. The high flow overcomes vacuum leaks at gaps between the wafer 119 and the top surface of wafer chuck 120 due to the highly bowed wafer shape. In some embodiments, a volumetric flow rate of at least 100 Liters per minute is induced between wafer chuck 120 and vacuum reservoir 131.

In some embodiments, high flow is maintained for several hundred milliseconds, allowing time for wafer 119 to deform from a highly bowed unforced shape to a flattened shape pressed against the top surface of wafer chuck 120. In some embodiments, high flow is maintained for at least five hundred milliseconds.

In the flattened state, a pressure differential between the top surface and the bottom surface of wafer 119 continues to force wafer 119 to adhere to the top surface of wafer chuck 120. The pressure differential is maintained between the atmospheric pressure acting at the top surface of wafer 119 and a negative pressure (vacuum) acting on the bottom surface of wafer 119 over vacuum channels in the top surface of wafer chuck 120. When wafer 119 is flattened against the top surface of wafer chuck 120, the bottom surface of wafer 119 is sealed against the top surface of wafer chuck 120. In this state, very little vacuum flow is required to maintain wafer 119 in a chucked state. In this state, pressurized air 123 flowing at very low rates through dynamic cables 115 and 116 is sufficient to maintain wafer 119 in the chucked state. As described hereinbefore, pressurized air 123 may be negatively pressurized air (vacuum) or positively pressurized air flowing through a venturi to generate vacuum applied to the bottom surface of wafer 119.

In a further aspect, the vacuum reservoir is fluidically coupled to a vacuum source configured to maintain the pressure of the vacuum reservoir. As depicted in FIG. 1, vacuum reservoir 131 is fluidically coupled to a vacuum source 102, e.g., a vacuum source on-board measurement system 100, a vacuum source integrated with a wafer processing facility and plumbed to measurement system 100. Vacuum reservoir 131 is fluidically coupled to wafer chuck 120 only when wafer chuck 120 is positioned in the docked position. Otherwise, wafer chuck 120 is decoupled from vacuum reservoir 131, e.g., when wafer 119 is moved below measurement subsystem 160 for measurements. During the time when wafer chuck 120 is decoupled from vacuum reservoir assembly 130, flow control valve 134 is closed and vacuum source 102 evacuates vacuum reservoir 131 to achieve a desired negative pressure within vacuum reservoir 131. In this manner, vacuum reservoir is prepared to induce high flow from wafer chuck 120 to vacuum reservoir 131 when the next highly bowed wafer must be clamped onto the top surface of wafer chuck 120.

FIG. 5 is plot 180 illustrative of the reservoir pressure and induced volumetric flow rate from a wafer chuck to a volumetric reservoir over a period of time before and after a flow control valve is opened in one example. As illustrated in FIG. 5, at time equal to zero, the flow control valve is opened. As depicted in FIG. 5, plotline 182 illustrates the measured pressure in a volumetric reservoir and plotline 181 illustrates the induced volumetric flow rate. Plotline 182 illustrates a sharp increase in pressure and plotline 181 illustrates a sharp increase in induced flow at the moment the flow control valve is opened. In the example depicted in FIG. 5, a peak volumetric flow rate of nearly 200 Liters per minute is achieved. Furthermore, a volumetric flow rate of more than 100 Liters per minute is maintained for over one second as the pressure in the volumetric reservoir rises toward a steady state value. As illustrated in FIG. 5, a vacuum reservoir fluidically coupled to a wafer chuck directly via a relatively short, large diameter conduit enables very high instantaneous vacuum flow rates to flatten highly bowed wafers.

In the embodiment depicted in FIG. 1, wafer positioning system 110 moves wafer chuck 120 horizontally, e.g., in the X-Y plane to a docked position where high flow vacuum port connector 132 and complementary high flow vacuum port connector 121 are fluidically coupled. In these embodiments the direction of engagement of the high flow vacuum port connector and the complementary high flow vacuum port connector is in the X-Y plane.

In some other embodiments, wafer positioning system 110 moves wafer chuck 120 vertically, e.g., in the Z- direction to a docked position where high flow vacuum port connector 132 and complementary high flow vacuum port connector 121 are fluidically coupled. In these embodiments the direction of engagement of the high flow vacuum port connector and the complementary high flow vacuum port connector is perpendicular to the X-Y plane. In general, the direction of engagement may be oriented in any suitable direction between the high flow vacuum port connector and complementary high flow vacuum port connector.

In some embodiments, a high flow vacuum port connector and a complementary high flow vacuum port connector are not in physical contact when fluidically coupled, e.g., during a high flow.

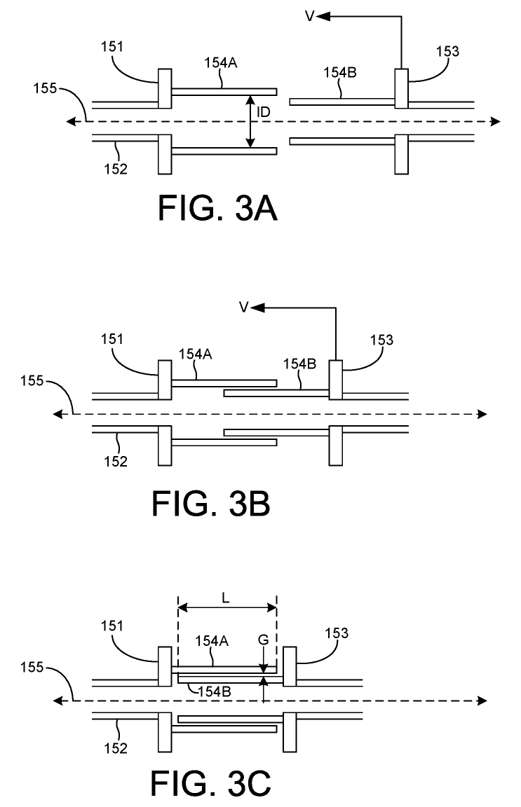

FIGS. 3A-C illustrate a high flow vacuum port connector and a complementary high flow vacuum port connector moving with respect to one another along a direction of engagement from an undocked state to a docked state in one embodiment.

FIGS. 3A-C illustrate a cross-sectional view of a high flow vacuum port connector 151 including a circular protrusion 154A, and complementary high flow vacuum port connector 153 including a complementary circular protrusion 154B. As depicted in FIGS. 3A-C, the inner diameter, ID, of circular protrusion 154A is larger than the outer diameter of circular protrusion 154B. As depicted in FIGS. 3A-C, high flow vacuum port connector 151 is coupled to vacuum conduit 155, which, in turn, is coupled to a vacuum reservoir (not shown). Furthermore, complementary high flow vacuum port connector 153 is coupled to a wafer chuck, directly, via a vacuum conduit, via a vacuum feedthrough, or both a vacuum conduit and a vacuum feedthrough.

As depicted in FIG. 3A, complementary high flow vacuum port connector 153 moves toward high flow vacuum port connector 151 at velocity, V, along a direction of engagement 155. As depicted in FIG. 3B, as complementary high flow vacuum port connector 153 engages with high flow vacuum port connector 151, the outer diameter of circular protrusion 154B moves within the inner diameter of circular protrusion 154A. As depicted in FIG. 3C, in the docked position, the outer diameter of circular protrusion 154B is disposed within the inner diameter of circular protrusion 154A over a length, L. Furthermore, a gap, G, exists between the outer diameter of circular protrusion 154B and the inner diameter of circular protrusion 154A. The inner diameter, ID, gap, G, and length, L, are selected to induce a relatively large resistance to flow, and thus, minimal vacuum leakage. In this manner, the non-contact fluidic coupling between high flow vacuum port connector 151 and complementary high flow vacuum port connector 153 in the docked position supports high flow from wafer chuck 120 to vacuum reservoir 131 with minimal losses. A non-contact fluidic coupling may be advantageous for a number of reasons. First, the non-contact fluidic coupling eliminates disturbance forces from being transmitted from the vacuum reservoir assembly to the wafer positioning system via the fluidic coupling. Second, the non-contact fluidic coupling eliminates any mechanical coupling of mass, mechanical stiffness, or both, from the vacuum reservoir assembly to the wafer positioning system. This prevents potential degradation or destabilization of positioning performance on the part of the wafer positioning system.

In some embodiments, a high flow vacuum port connector and a complementary high flow vacuum port connector are in physical contact when fluidically coupled, e.g., during a high flow. In some of these embodiments, the high flow vacuum port connector, the complementary high flow vacuum port connector, or both, include a bellows structure.

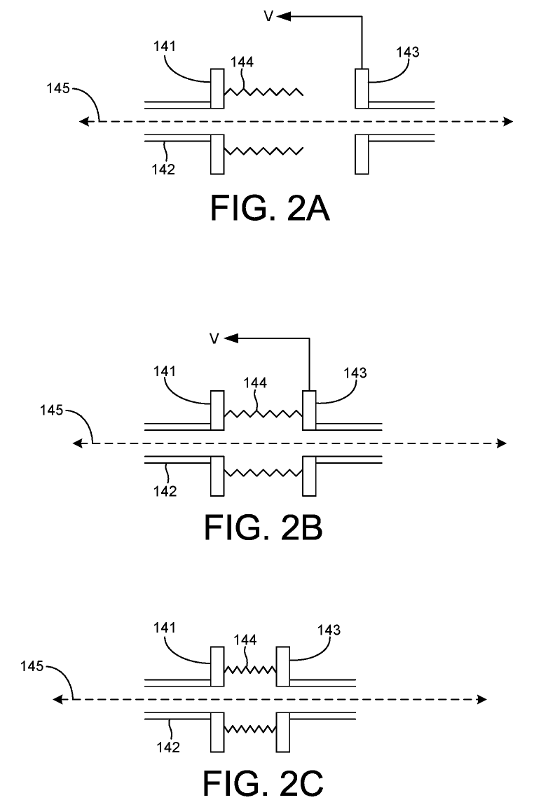

FIGS. 2A-C illustrate a high flow vacuum port connector and a complementary high flow vacuum port connector moving with respect to one another along a direction of engagement from an undocked state to a docked state in one embodiment.

FIGS. 2A-C illustrate a cross-sectional view of a high flow vacuum port connector 141 including a bellows structure 144 and a complementary high flow vacuum port connector 143. As depicted in FIGS. 2A-C, high flow vacuum port connector 141 is coupled to vacuum conduit 142, which, in turn, is coupled to a vacuum reservoir (not shown). Furthermore, complementary high flow vacuum port connector 143 is coupled to a wafer chuck, directly, via a vacuum conduit, via a vacuum feedthrough, or both a vacuum conduit and a vacuum feedthrough.

As depicted in FIG. 2A, complementary high flow vacuum port connector 143 moves toward high flow vacuum port connector 141 at velocity, V, along a direction of engagement 145. As depicted in FIG. 2B, as complementary high flow vacuum port connector 143 engages with high flow vacuum port connector 141, bellows 144 engages with a surface of complementary high flow vacuum port connector 143. As depicted in FIG. 2C, in the docked position, bellows 144 is compressed to form a seal at the surface of complementary high flow vacuum port connector 143. In some embodiment, a sealing ring, e.g., silicone ring, is integrated with the surface of complementary high flow vacuum port connector 143, or the portion of bellows 144 in contact with the surface of complementary high flow vacuum port connector 143, to enhance sealing at the interface. In this manner, the fluidic coupling between high flow vacuum port connector 141 and complementary high flow vacuum port connector 143 in the docked position supports high flow from wafer chuck 120 to vacuum reservoir 131 with minimal losses. A contact-type fluidic coupling employing a bellows structure having a low stiffness along the direction of engagement and in directions perpendicular to the direction of engagement may be advantageous for a number of reasons. First, the compliant bellows coupling minimizes disturbance forces from being transmitted from the vacuum reservoir assembly to the wafer positioning system via the fluidic coupling. Second, the compliant bellows coupling minimizes any mechanical coupling of mass, mechanical stiffness, or both, from the vacuum reservoir assembly to the wafer positioning system. This prevents potential degradation or destabilization of positioning performance on the part of the wafer positioning system.

In some embodiments, the high flow vacuum port connector remains in the same position relative to the machine frame in the undocked and docked configurations. In the embodiment depicted in FIG. 1, wafer positioning system 110 moves wafer chuck 120 to the docked position with respect to the vacuum reservoir assembly 130 to engage the high flow vacuum port connector 132 and complementary high flow vacuum port connector 121 and realize the fluidic coupling between the two.

In a further aspect, a measurement system includes an actuator subsystem configured to move the high flow vacuum port connector with respect to the machine frame in a direction aligned with a direction of engagement of the high flow vacuum port connector and the complementary high flow vacuum port connector to realize the fluidic coupling between the two.

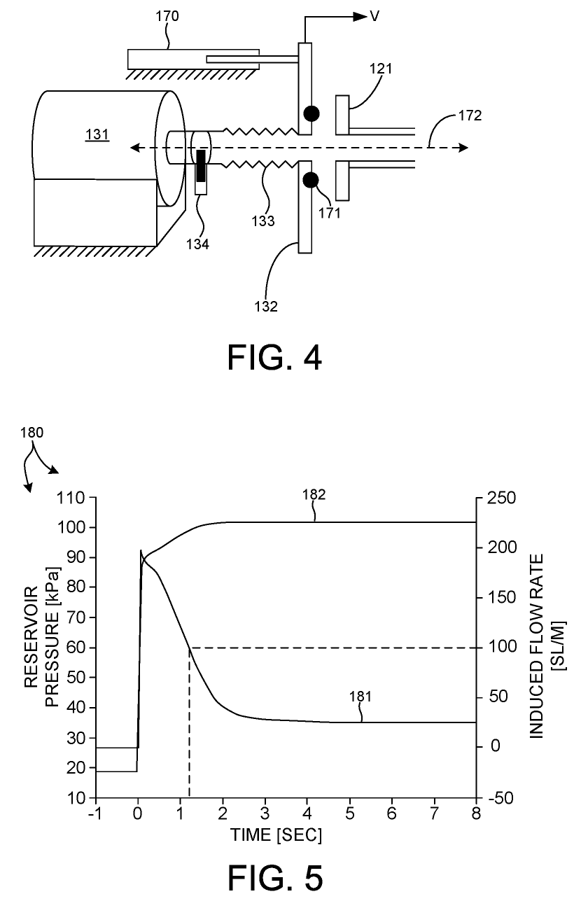

FIG. 4 is a diagram including an actuator subsystem 170 configured to move the high flow vacuum port connector 132 of vacuum reservoir assembly 130 toward the complementary high flow vacuum port connector 121 along a direction of engagement 172 at velocity, V. As depicted in FIG. 4, an O-ring 171 is integrated with a surface of high flow vacuum port connector 132 facing complementary high flow vacuum port connector 121. In the docked position, O- ring 171 is compressed to form a seal at the surface of complementary high flow vacuum port connector 121. In this manner, the fluidic coupling between high flow vacuum port connector 132 and complementary high flow vacuum port connector 121 in the docked position supports high flow from wafer chuck 120 to vacuum reservoir 131 with minimal losses.

In some embodiments, the docked position is the same position of wafer chuck 120 with respect to machine frame 101 employed by a semiconductor measurement system when changing wafers.

FIG. 1 illustrates a simplified schematic of an optical metrology or inspection system 160 positioned to inspect wafer 119 or perform measurements of structures formed on wafer 119. In some embodiments, system 160 is configured as a scanning system. In some other embodiments system 160 is configured as a point to point measurement system. In the depicted embodiment, wafer 119 is vacuum clamped to wafer chuck 120, while wafer chuck 120 is moved in multiple degrees of freedom by wafer positioning system 110.

As illustrated in FIG. 1, wafer 119 is illuminated by a normal incidence beam 163 generated by one or more illumination sources 161. Alternatively, the illumination subsystem may be configured to direct the beam of light to the specimen at an oblique angle of incidence. In some embodiments, system 160 may be configured to direct multiple beams of light to the specimen such as an oblique incidence beam of light and a normal incidence beam of light. The multiple beams of light may be directed to the specimen substantially simultaneously or sequentially.

Illumination source 161 may include, by way of example, a laser, a diode laser, a helium neon laser, an argon laser, a solid state laser, a diode pumped solid state (DPSS) laser, a xenon arc lamp, a gas discharging lamp, and LED array, or an incandescent lamp. The light source may be configured to emit near monochromatic light or broadband light. The illumination subsystem may also include one or more spectral filters that may limit the wavelength of the light directed to the specimen. The one or more spectral filters may be bandpass filters and/or edge filters and/or notch filters.

Normal incidence beam 163 is focused onto the substrate 110 by an objective lens 164. System 160 includes collection optics 162 to collect the light scattered and/or reflected by wafer 119 in response to the illumination light 163. Collection optics 162 focus the collected light onto a detector 165. The output signals 166 generated by detector 165 are supplied to a computing system 167 for processing the signals and determining the measurement parameter values (e.g., material or structural properties, dimensions, presence of particles, etc.). System 160 is presented herein by way of non-limiting example, as vacuum reservoir assembly 130 may be implemented within many different electron based, x-ray based, or optical based metrology and inspection systems.

As illustrated in FIG. 1, the system 160 is configured as an inspection system or a metrology system. In this manner, the system may be configured to inspect or measure wafers and reticles used as part of a semiconductor manufacturing process. The methods and systems described herein are not limited to the inspection or measurement of semiconductor wafers or reticles, and may be applied to the inspection of other substrates that need to be chucked to a flat surface for processing.

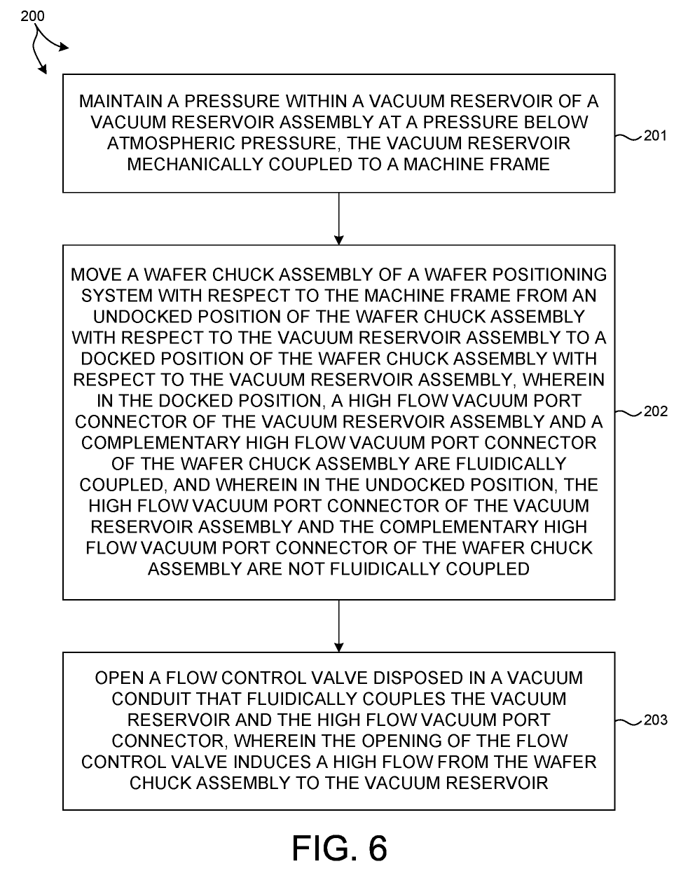

FIG. 6 illustrates a flowchart of an exemplary method 200 useful for vacuum clamping and unclamping warped substrates onto a vacuum chuck in several novel aspects. By way of non-limiting example, method 200 is described with reference to the vacuum chuck system 100 illustrated in FIG. 1 for explanatory purposes. Although, the description of system 100 includes references to specific hardware elements employed to achieve the elements of method 200, many other hardware elements known to persons of ordinary skill in the art may be contemplated to achieve an analogous result. Hence, any of the referenced hardware elements presented herein may be substituted, consolidated, modified, or eliminated without exceeding the scope of the description provided herein. Similarly, some of the elements of method 200 and the order of presentation of the elements of method 200 relate to the use of specific hardware elements described with reference to system 100. However, as many other hardware elements known to persons of ordinary skill in the art may be contemplated to achieve an analogous result, some of the method elements and the order of presentation of the method elements may be substituted, consolidated, modified, or eliminated without exceeding the scope of the description provided herein.

In block 201, a pressure is maintained within a vacuum reservoir of a vacuum reservoir assembly at a pressure below atmospheric pressure. The vacuum reservoir is mechanically coupled to a machine frame.

In block 202, a wafer chuck assembly of a wafer positioning system is moved with respect to the machine frame from an undocked position of the wafer chuck assembly with respect to the vacuum reservoir assembly to a docked position of the wafer chuck assembly with respect to the vacuum reservoir assembly. In the docked position, a high flow vacuum port connector of the vacuum reservoir assembly and a complementary high flow vacuum port connector of the wafer chuck assembly are fluidically coupled. In the undocked position, the high flow vacuum port connector of the vacuum reservoir assembly and the complementary high flow vacuum port connector of the wafer chuck assembly are not fluidically coupled.

In block 203, a flow control valve disposed in a vacuum conduit that fluidically couples the vacuum reservoir and the high flow vacuum port connector is opened. The opening of the flow control valve induces a high flow from the wafer chuck assembly to the vacuum reservoir when the high flow vacuum port connector of the vacuum reservoir assembly and the complementary high flow vacuum port connector of the wafer chuck assembly are fluidically coupled.

The aforementioned embodiments of a vacuum chuck system are presented by way of non-limiting example. Other configurations may also be contemplated within the scope of this disclosure.

Embodiments of the present invention allow for effective chucking of concave, convex, or asymmetrically warped substrates, independent of shape. Furthermore, these embodiments handle wafers with a maximum out of plane distortion that is greater than 8 millimeters. The vacuum reservoir assembly described herein can be a drop-in addition for existing semiconductor measurement or processing tools.

Embodiments of the present invention can increase throughput of substrates when necessary for warped wafers, thereby saving time during normal wafer operation. Embodiments also allow processing of warped wafers, which could not previously have been processed due the amount of warpage.

Various embodiments are described herein for a semiconductor processing system (e.g., an inspection system, a metrology system, a lithographic system, an etch system, etc.). The term "substrate" is used herein to refer to a wafer, a reticle, or any other sample that may be processed (e.g., printed or inspected for defects) by means known in the art.

As used herein, the term "wafer" generally refers to substrates formed of a semiconductor or non- semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be "patterned" or "unpatterned." For example, a wafer may include a plurality of dies having repeatable pattern features.

A "reticle" may be a reticle at any stage of a reticle fabrication process, or a completed reticle that may or may not be released for use in a semiconductor fabrication facility. A reticle, or a "mask," is generally defined as a substantially transparent substrate having substantially opaque regions formed thereon and configured in a pattern. The substrate may include, for example, a glass material such as quartz. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer- readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special- purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A semiconductor measurement system, comprising:
a machine frame;
a vacuum reservoir assembly mechanically coupled to the machine frame, the vacuum reservoir assembly comprising:
a vacuum reservoir configured to be maintained at a pressure below atmospheric pressure;
a high flow vacuum port connector fluidically coupled to the vacuum reservoir; and
a flow control valve disposed in a fluidic path between the vacuum reservoir and the high flow vacuum port connector;
a wafer positioning system mechanically coupled to the machine frame, the wafer positioning system comprising:
a wafer chuck assembly including a complementary high flow vacuum port connector;
at least one linear stage configured to move the wafer chuck assembly with respect to the machine frame in at least one degree of freedom, wherein in a docked position of the wafer chuck assembly with respect to the vacuum reservoir assembly, the high flow vacuum port connector and the complementary high flow vacuum port connector are fluidically coupled, and wherein in an undocked position of the wafer chuck assembly with respect to the vacuum reservoir assembly, the high flow vacuum port connector and the complementary high flow vacuum port connector are fluidically decoupled.

2. The semiconductor measurement system of claim 1, wherein in a high flow vacuum state the wafer chuck assembly is in the docked position, the flow control valve is open, and a high flow is induced from the wafer chuck to the vacuum reservoir.

3. The semiconductor measurement system of claim 1, wherein the vacuum reservoir is fluidically coupled to a vacuum source configured to maintain the pressure of the vacuum reservoir.

4. The semiconductor measurement system of claim 1, the vacuum chuck assembly comprising:
a wafer chuck configured to rotate about an axis of rotation; and
a vacuum feedthrough assembly configured to supply positively or negatively pressurized air to the wafer chuck from the wafer positioning system, wherein the complementary high flow vacuum port connector is mechanically coupled to the wafer chuck or the vacuum feedthrough assembly.

5. The semiconductor measurement system of claim 1, wherein the fluidic path from the vacuum reservoir to the wafer chuck in the docked position is less than one meter.

6. The semiconductor measurement system of claim 2, wherein the high flow exceeds 100 Liters per minute for a period of time.

7. The semiconductor measurement system of claim 6, wherein the period of time is greater than 500 milliseconds.

8. The semiconductor measurement system of claim 1, wherein a direction of engagement of the high flow vacuum port connector and the complementary high flow vacuum port connector is in a direction perpendicular to a direction of the one degree of freedom or in a direction aligned with the direction of the at least one degree of freedom.

9. The semiconductor measurement system of claim 1, further comprising:
an actuator subsystem configured to move the high flow vacuum port connector with respect to the machine frame in a direction aligned with a direction of engagement of the high flow vacuum port connector and the complementary high flow vacuum port connector.

10. The semiconductor measurement system of claim 2, wherein the high flow vacuum port connector and the complementary high flow vacuum port connector are not in contact during the high flow.

11. The semiconductor measurement system of claim 2, wherein the high flow vacuum port connector includes a bellows structure, and wherein the high flow vacuum port connector and the complementary high flow vacuum port connector are in contact during the high flow.

12. A method comprising:
maintaining a pressure within a vacuum reservoir of a vacuum reservoir assembly at a pressure below atmospheric pressure, the vacuum reservoir mechanically coupled to a machine frame;
moving a wafer chuck assembly of a wafer positioning system with respect to the machine frame from an undocked position of the wafer chuck assembly with respect to the vacuum reservoir assembly to a docked position of the wafer chuck assembly with respect to the vacuum reservoir assembly, wherein in the docked position, a high flow vacuum port connector of the vacuum reservoir assembly and a complementary high flow vacuum port connector of the wafer chuck assembly are fluidically coupled, and wherein in the undocked position, the high flow vacuum port connector of the vacuum reservoir assembly and the complementary high flow vacuum port connector of the wafer chuck assembly are not fluidically coupled; and
opening a flow control valve disposed in a vacuum conduit that fluidically couples the vacuum reservoir and the high flow vacuum port connector, wherein the opening of the flow control valve induces a high flow from the wafer chuck assembly to the vacuum reservoir when the high flow vacuum port connector of the vacuum reservoir assembly and the complementary high flow vacuum port connector of the wafer chuck assembly are fluidically coupled.

13. The method of claim 12, wherein a fluidic path from the vacuum reservoir to the wafer chuck in the docked position is less than one meter.

14. The method of claim 12, wherein the high flow exceeds 100 Liters per minute for a period of time.

15. The method of claim 14, wherein the period of time is greater than 500 milliseconds.

16. The method of claim 12, further comprising:
moving the high flow vacuum port connector with respect to the machine frame in a direction aligned with a direction of engagement of the high flow vacuum port connector and the complementary high flow vacuum port connector.

17. The method of claim 12, wherein the high flow vacuum port connector and the complementary high flow vacuum port connector are not in contact during the high flow.

18. A vacuum chuck system, comprising:
a vacuum reservoir assembly mechanically coupled to a machine frame, the vacuum reservoir assembly comprising:
a vacuum reservoir configured to be maintained at a pressure below atmospheric pressure;
a high flow vacuum port connector fluidically coupled to the vacuum reservoir; and
a flow control valve disposed in a fluidic path between the vacuum reservoir and the high flow vacuum port connector; and
a wafer positioning system mechanically coupled to the machine frame, the wafer positioning system comprising:
a wafer chuck assembly including a complementary high flow vacuum port connector;
at least one linear stage configured to move the wafer chuck assembly with respect to the machine frame in at least one degree of freedom, wherein in a docked position of the wafer chuck assembly with respect to the vacuum reservoir assembly, the high flow vacuum port connector and the complementary high flow vacuum port connector are fluidically coupled, and wherein in an undocked position of the wafer chuck assembly with respect to the vacuum reservoir assembly, the high flow vacuum port connector and the complementary high flow vacuum port connector are fluidically decoupled.

19. The vacuum chuck system of claim 18, wherein the high flow vacuum port connector and the complementary high flow vacuum port connector are not in contact in the docked position.

20. The vacuum chuck system of claim 18, wherein the high flow vacuum port connector includes a bellows structure, and wherein the high flow vacuum port connector and the complementary high flow vacuum port connector are in contact in the docked position.
